(19) United States
(12) Patent Application Publication
(10) Pub. No.: US 2012/0069525 A1
(43) Pub. Date: Mar. 22, 2012

(54) ASSEMBLED STRUCTURE OF ELECTRONIC COMPONENT AND HEAT-DISSIPATING DEVICE

(75) Inventor: Ming-Tang Yang, Taoyuan Hsien (TW)

(73) Assignee: DELTA ELECTRONICS, INC., Taoyuan Hsien (TW)

(21) Appl. No.: 13/103,021

(22) Filed: May 6, 2011

(30) Foreign Application Priority Data
Sep. 21, 2010 (TW) 099132071

(51) Int. Cl. H05K 7/20

(52) U.S. Cl. 361/718; 361/688

(57) ABSTRACT

An assembled structure includes an electronic component, a heat-dissipating device and a stepped isolation member. The electronic component has a first perforation. The heat-dissipating device has a second perforation corresponding to the first perforation of the electronic component. The stepped isolation member includes a first segment, a second segment and a third segment. The outer diameter of the first segment is smaller than the outer diameter of the second segment, and the outer diameter of the second segment is smaller than the outer diameter of the third segment. The first segment is partially accommodated within the first perforation of the electronic component, the second segment is arranged between the first segment and the third segment and engaged with the second perforation of the heat-dissipating device, and the third segment is contacted with the heat-dissipating device.

### FIELD OF THE INVENTION

The present invention relates to an assembled structure of an electronic component and a heat-dissipating device, and more particularly to an assembled structure of an electronic component and a heat-dissipating device for enhancing electric safety.

### BACKGROUND OF THE INVENTION

With the rapid progress of semiconductor industries, the integrated circuits (ICs) used in various electronic devices are developed toward minimization, high operating speed and high integration level. Due to the reduced size and the increased performance, power semiconductor devices such as power transistors have achieved a great deal of advance. The power transistors are widely used in many electronic apparatuses such as control equipment, measuring equipment, electrical apparatuses and computer peripheral devices because they are very suitable to process high-power signals. During operation of the electronic apparatus, the power transistors may generate energy in the form of heat, which is readily accumulated and difficult to dissipate away. If no proper heat-dissipating mechanism is provided to transfer enough heat to the ambient air, the elevated operating temperature may result in damage of the electronic component, a breakdown of the whole electronic device or reduced operation efficiency. Therefore, it is important to dissipate the heat generated from the power transistors in order to stabilize the operation and extend the operational life of the electronic device.

Typically, the power transistors are fastened on a surface of a heat sink in order to increase heat-dissipating efficiency. FIG. 1A is a schematic exploded view illustrating a mechanism for fixing a power transistor on a heat sink according to the prior art. FIG. 1B is a schematic perspective view illustrating the assembled structure of the power transistor and the heat sink of FIG. 1A. By penetrating a screw 14 through a perforation 131 of a plastic bushing 13, a perforation 111 of a power transistor 11, a perforation 161 of an insulating piece 16, a perforation 121 of a heat sink 12 and a nut 15, the power transistor 11 can be fastened on the heat sink 12. In addition, by means of the plastic bushing 13 and the insulating piece 16, the power transistor 11 is separated from the screw 14 and the heat sink 12, respectively. In such way, the problems of causing spark generation and short-circuit breakdown will be avoided.

Generally, the diameters of the perforations 111, 161 and 121 of the power transistor 11, the insulating piece 16 and the heat sink 12 are substantially identical. Consequently, the minimum distance between the perforation 111 of the power transistor 11 and the perforation 121 of the heat sink 12 is substantially equal to the thickness of the insulating piece 16. In addition, for providing thermal conduction between the power transistor 11 and the heat sink 12, the thickness of the insulating piece 16 should be as thin as possible. Since the insulating distance is insufficient, if a high voltage is applied to the power transistor 11, the power transistor 11 is readily short-circuited or the electrical property thereof is impaired. Under this circumstance, the use life of the electronic device is shortened or the safety of the electronic device is deteriorated.

For solving the above drawbacks, the inner periphery of the perforation 121 of the heat sink 12′ has a beveled edge 122 (see FIG. 1C). In this situation, the distance between the power transistor 11 and the heat sink 12′ is extended by an additional gap S. The additional gap S may increase the insulating efficacy. However, the beveled edge 122 may reduce the structural strength of the heat sink 12′.

FIG. 2A is a schematic exploded view illustrating another mechanism for fixing a power transistor on a heat sink according to the prior art. FIG. 2B is a schematic cross-sectional view illustrating the assembled structure of the power transistor and the heat sink of FIG. 2A. By means of a screw 24, a fixing member 23 and a nut 25, a power transistor 21 is fixed on a heat sink 22. The fixing member 23 comprises a perforation 231 and a protrusion 232. The protrusion 232 is penetrated through a perforation 211 of the power transistor 21. By successively penetrating the screw 24 through a perforation 221 of the heat sink, a perforation 261 of an insulating piece 26 and the perforation 231 of the fixing member 23 and tightening the screw 24 in the nut 25, the power transistor 21 is indirectly attached on the heat sink 22 through the fixing member 23 and the insulating piece 26. Due to a gap G between the perforation 231 and the protrusion 232 of the fixing member 23, the electric safety is enhanced. However, since it is necessary to retain the gap G between the perforation 231 and the protrusion 232, the overall height of the heat sink 22 will be increased. That is, the gap G is detrimental to miniaturization of the electronic device.

For obviating the drawbacks encountered from the prior art, there is a need of providing an assembled structure of an electronic component and a heat-dissipating device.

### SUMMARY OF THE INVENTION

The present invention provides an assembled structure of an electronic component and a heat-dissipating device for enhancing electric safety without increasing the overall height and impairing the structural strength of the heat-dissipating device.

In accordance with an aspect of the present invention, there is provided an assembled structure. The assembled structure includes an electronic component, a heat-dissipating device and a stepped isolation member. The electronic component has a first perforation. The heat-dissipating device has a second perforation corresponding to the first perforation of the electronic component. The stepped isolation member includes a first segment, a second segment and a third segment. The outer diameter of the first segment is smaller than the outer diameter of the second segment, and the outer diameter of the second segment is smaller than the outer diameter of the third segment. The first segment is partially accommodated within the first perforation of the electronic component, the second segment is arranged between the first segment and the third segment and engaged with the second perforation of the heat-dissipating device, and the third segment is contacted with the heat-dissipating device.

In accordance with another aspect of the present invention, there is provided a stepped isolation member for use in an assembled structure of an electronic component and a heat-dissipating device. The electronic component has a first perforation. The heat-dissipating device has a second perforation corresponding to the first perforation. The stepped isolation member includes a first segment, a second segment and a third segment. The second segment is arranged between the first segment and the third segment. The outer diameter of the first segment is smaller than the outer diameter of the second segment, and the outer diameter of the second segment is smaller than the outer diameter of the third segment. The first segment is partially accommodated within the first perforation of the electronic component, the second segment is engaged with the second perforation of the heat-dissipating device, and the third segment is contacted with the heat-dissipating device.

The above contents of the present invention will become more readily apparent to those ordinarily skilled in the art after reviewing the following detailed description and accompanying drawings, in which:

### BRIEF DESCRIPTION OF THE DRAWINGS

FIG. 1A is a schematic exploded view illustrating a mechanism for fixing a power transistor on a heat sink according to the prior art;

FIG. 1B is a schematic perspective view illustrating the assembled structure of the power transistor and the heat sink of FIG. 1A;

FIG. 1C is a schematic cross-sectional view illustrating the assembled structure of FIG. 1B taken along the line a-a′, in which the inner periphery of the perforation of the heat sink has a beveled edge;

FIG. 2A is a schematic exploded view illustrating another mechanism for fixing a power transistor on a heat sink according to the prior art;

FIG. 2B is a schematic perspective view illustrating the assembled structure of the power transistor and the heat sink of FIG. 2A;

FIG. 3A is a schematic exploded view illustrating a mechanism for fixing an electronic component on a heat-dissipating device according to a first embodiment of the present invention;

FIG. 3B is a schematic perspective view illustrating the isolation member used in the assembled structure of FIG. 3A;

FIG. 3C is a schematic perspective view illustrating the isolation member of FIG. 3B taken along the line a-a′;

FIG. 3D is a schematic cross-sectional view illustrating the assembled structure of FIG. 3A;

FIG. 4 is a schematic perspective view illustrating another exemplary isolation member used in the assembled structure of the present invention; and

FIG. 5 is a schematic perspective view illustrating another exemplary isolation member used in the assembled structure of the present invention.

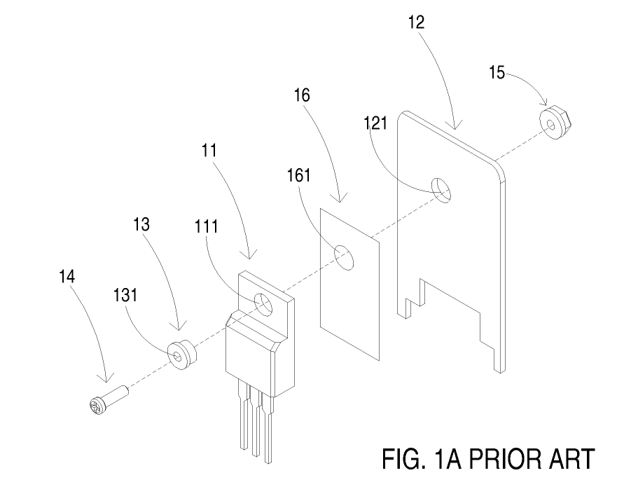

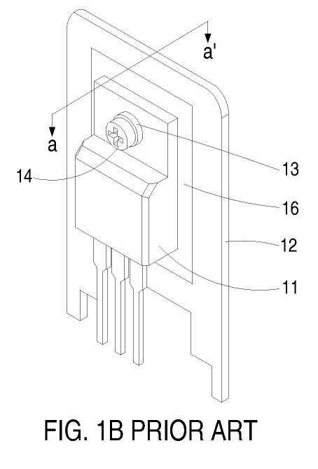

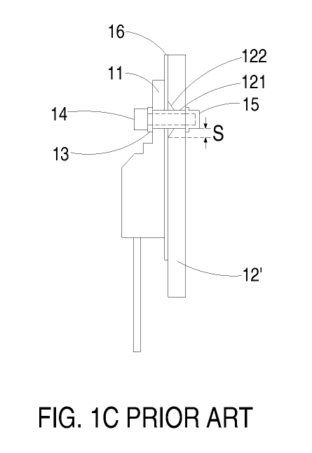

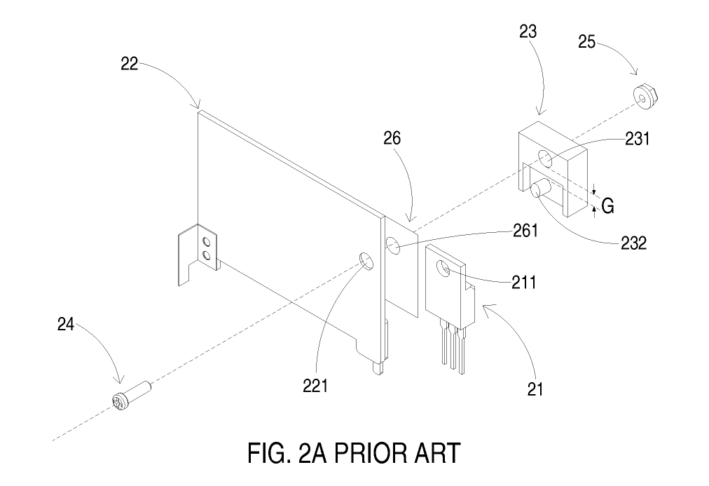

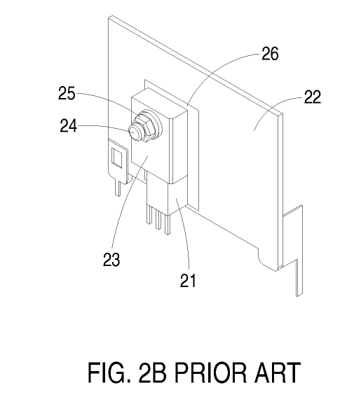

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

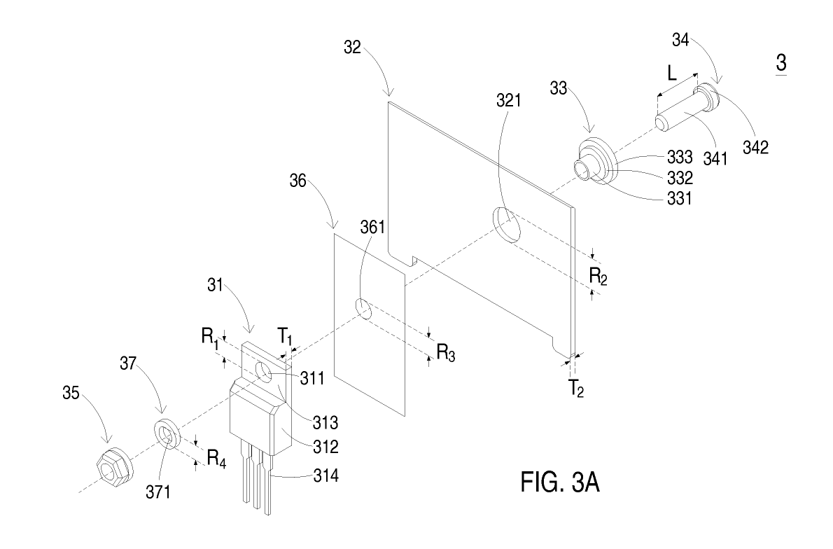

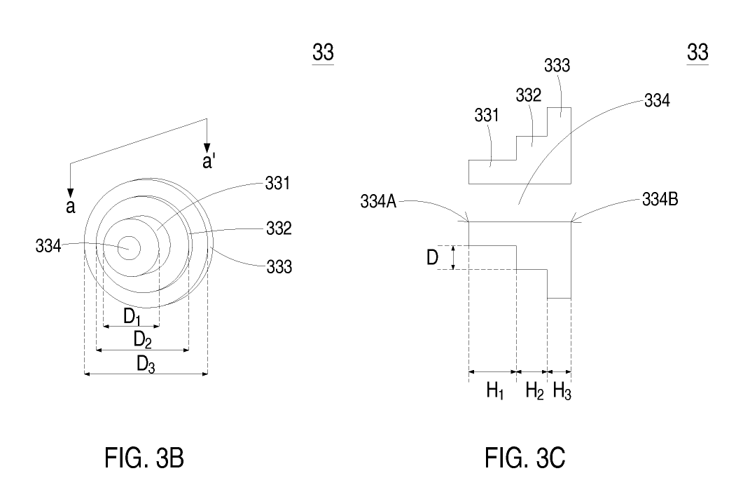

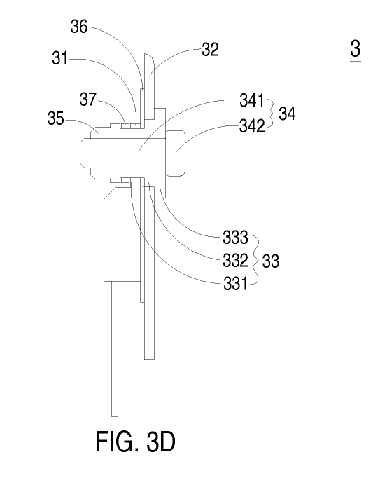

FIG. 3A is a schematic exploded view illustrating a mechanism for fixing an electronic component on a heat-dissipating device according to a first embodiment of the present invention. As shown in FIG. 3A, the assembled structure 3 comprises an electronic component 31, a heat-dissipating device 32 and an isolation member 33. The electronic component 31 has a first perforation 311. The heat-dissipating device 32 has a second perforation 321 corresponding to the first perforation 311. The isolation member 33 has a stepped shape. The isolation member 33 comprises a first segment 331, a second segment 332 and a third segment 333. The outer diameter of the first segment 331 is smaller than the outer diameter of the second segment 332. The outer diameter of the second segment 332 is smaller than the outer diameter of the third segment 333. The first segment 331 is partially accommodated within the first perforation 311 of the electronic component 31 (see FIG. 3D). The second segment 332 is arranged between the first segment 331 and the third segment 333, and engaged with the second perforation 321 of the heat-dissipating device 32. The third segment 333 is contacted with the heat-dissipating device 32.

Hereinafter, the assembled structure of the electronic component and the heat-dissipating device and the configurations of the isolation member will be illustrated in more details.

Please refer to FIG. 3A again. An example of the electronic component 31 includes but is not limited to a transistor (e.g. a power transistor). The electronic component 31 comprises first perforation 311, a main body 312, a metallic plate 313 and plural pins 314. The metallic plate 313 is extended from the main body 312 and has a thickness T1. The heat generated from the electronic component 31 may be dissipated away through the metallic plate 313. The first perforation 311 is formed in the metallic plate 313. In this embodiment, the first perforation 311 is a circular hole with a diameter R1. It is noted that the first perforation 311 is not limited to the circular hole. For example, the first perforation 311 may be a rectangular hole, a polygonal hole or an irregular hole. An example of the heat-dissipating device 32 includes but is not limited to a heat sink with a thickness T2. The second perforation 321 of the heat-dissipating device 32 is a circular hole with a diameter R2. It is noted that the second perforation 321 is not limited to the circular hole.

FIG. 3B is a schematic perspective view illustrating the isolation member used in the assembled structure of FIG. 3A. FIG. 3C is a schematic perspective view illustrating the isolation member of FIG. 3B taken along the line a-a′. The isolation member 33 comprises the first segment 331, the second segment 332 and the third segment 333. The second segment 332 is arranged between the first segment 331 and the third segment 333. The first segment 331, the second segment 332 and the third segment 333 are made of insulating material and integrally formed. In this embodiment, the first segment 331, the second segment 332 and the third segment 333 are cylindrical posts, which are coaxial with each other. That is, the geometric centers of the first segment 331, the second segment 332 and the third segment 333 are arranged in the same line (e.g. the centerline). The outer diameter D1 of the first segment 331 is smaller than the outer diameter D2 of the second segment 332. The outer diameter D2 of the second segment 332 is smaller than the outer diameter D3 of the third segment 333. Since the cross sections of the segments 331, 332 and 333 perpendicular to the centerline are circular, the outer diameters are equivalent to the diameters thereof. In this embodiment, the length H1 of the first segment 331 is larger than the length H2 of the second segment 332, and the height H2 of the second segment 332 is larger than the height H3 of the third segment 333. It is noted that the lengths H1, H2 and H3 of the segments 331, 332 and 333 may be adjusted according to the practical requirements. That is, since the outer diameters of the segments 331, 332 and 333 are gradually increased, the isolation member 33 has a stepped shape (see FIG. 3C).

Moreover, the isolation member 33 has a channel 334. The channel 334 runs through the first segment 331, the second segment 332 and the third segment 333 along the centerline. The channel 334 has a first mouth part 334A and a second mouth part 334B, which have the same diameter. The first mouth part 334A and the second mouth part 334B are opposed to each other, wherein the first mouth part 334A is arranged beside the first segment 331 and the second mouth part 334B is arranged beside the third segment 333.

Please refer to FIGS. 3A, 3B and 3C again. The first segment 331 of the isolation member 33 corresponds to the first perforation 311 of the electronic component 31. The outer diameter D1 of the first segment 331 is slightly smaller than the diameter R1 of the first perforation 311. The length H1 of the first segment 331 is larger than the thickness T1 of the metallic plate 313 of the electronic component 31. The second segment 332 of the isolation member 33 corresponds to the second perforation 321 of the heat-dissipating device 32. The outer diameter D2 of the second segment 332 is substantially equal to the diameter R2 of the second perforation 321 of the heat-dissipating device 32. The height H2 of the second segment 332 is substantially equal to the thickness T2 of the heat-dissipating device 32.

Please refer to FIG. 3A again. In addition to the electronic component 31, the heat-dissipating device 32 and the isolation member 33, the assembled structure 3 further comprises a first fastening element 34, a second fastening element 35 and an insulating piece 36. The first fastening element 34 and the second fastening element 35 are configured to assist in fixing the electronic component 31 on the heat-dissipating device 32. The insulating piece 36 is configured to isolate associated components. The first fastening element 34 comprises a body part 341 and a head part 342. The length of the body part 341 of the first fastening element 34 is larger than the sum of the lengths H1, H2 and H3 of the segments 331, 332 and 333, so that the first fastening element 34 is penetrable through the channel 334 of the isolation member 33. The second fastening element 35 is coupled with the body part 341 of the first fastening element 34. In this embodiment, the first fastening element 34 and the second fastening element 35 are a screw and a nut, respectively.

The insulating piece 36 is arranged between the heat-dissipating device 32 and the electronic component 31. The insulating piece 36 has a third perforation 361. The diameter R3 of the third perforation 361 is substantially equal to the diameter R1 of the first perforation 311 of the electronic component 31. In addition, the diameter R3 of the third perforation 361 is smaller than the diameter R2 of the second perforation 321 of the heat-dissipating device 32. For increasing the insulating efficacy, the assembled structure 3 is optionally provided with an insulating washer 37. The washer 37 is arranged between the electronic component 31 and the second fastening element 35. The washer 37 has a fourth perforation 371. The diameter R4 of the fourth perforation 371 is substantially equal to the diameter R1 of the first perforation 311 and the diameter R3 of the third perforation 361.

FIG. 3D is a schematic cross-sectional view illustrating the assembled structure of FIG. 3A. Hereinafter, a process of fabricating the assembled structure 3 will be illustrated with reference to FIGS. 3A, 3B. 3C and 3D. Firstly, the first segment 331 of the isolation member 33 is successively penetrated through the second perforation 321 of the heat-dissipating device 32, the third perforation 361 of the insulating piece 36, the first perforation 311 of the electronic component 31 and the fourth perforation 371 of the washer 37. Since the outer diameter D2 of the second segment 332 of the isolation member 33 is substantially equal to the diameter R2 of the second perforation 321 of the heat-dissipating device 32 and the diameter R2 of the second perforation 321 is larger than the diameter R3 of the third perforation 361, the second segment 332 of the isolation member 33 fails to be penetrated through the third perforation 361. Meanwhile, the second segment 332 of the isolation member 33 is engaged with the second perforation 321 of the heat-dissipating device 32. Moreover, since the outer diameter D3 of the third segment 333 of the isolation member 33 is larger than the outer diameter D2 of the second segment 332, the third segment 333 fails to be penetrated through the second perforation 321. Since the height H2 of the second segment 332 is substantially equal to the thickness T2 of the heat-dissipating device 32, the second segment 332 is completely received within the second perforation 321 and the third segment 333 is contacted with the heat-dissipating device 32. The body part 341 of the first fastening element 34 is inserted into the channel 334 of the isolation member 33 through the second mouth part 334B and protruded out of the first mouth part 334A. Consequently, the body part 341 of the first fastening element 34 is coupled with the second fastening element 35, which is arranged beside the first segment 331 of the isolation member 33. The head part 342 of the first fastening element 34 is contacted with the third segment 333 of the isolation member 33. Consequently, the head part 342 of the first fastening element 34 is isolated from the heat-dissipating device 32 through the third segment 333 of the isolation member 33. In such way, the washer 37, the electronic component 31, the insulating piece 36 and the heat-dissipating device 32 will be combined together. Meanwhile, the third segment 333 of the isolation member 33 and the head part 342 of the first fastening element 34 are arranged at a first side of the heat-dissipating device 32, and the second fastening element 35, the washer 37, the electronic component 31 and the insulating piece 36 are arranged at a second side of the heat-dissipating device 32 (see FIG. 3D).

Since the second segment 332 of the isolation member 33 is engaged with the heat-dissipating device 32 and the outer diameter D2 of the second segment 332 is larger than the outer diameter D1 of the first segment 331, the gap D between the outer diameter D2 and the outer diameter D1 (see FIG. 3C) may increase the insulating distance between the electronic component 31 and the heat-dissipating device 32. Moreover, since the second segment 332 of the isolation member 33 is engaged with the second perforation 321 of the heat-dissipating device 32, the structural strength of the heat-dissipating device 32 is not impaired. Moreover, since the outer diameter D2 of the second segment 332 and the diameter R2 of the second perforation 321 of the heat-dissipating device 32 are increased, the gap D between the outer diameter D2 and the outer diameter D1 is increased. Under this circumstance, the insulating distance between the electronic component 31 and the heat-dissipating device 32 will be increased. Even if a high voltage is applied to the electronic component 31, the short-circuited problem will be avoided. Moreover, the length H3 of the third segment 333 of the isolation member 33 may be adjusted according to the practical requirements. Consequently, a proper insulating distance between the head part 342 of the first fastening element 34 and the heat-dissipating device 32 will be retained through the third segment 333 of the isolation member 33, thereby enhancing the electric safety.

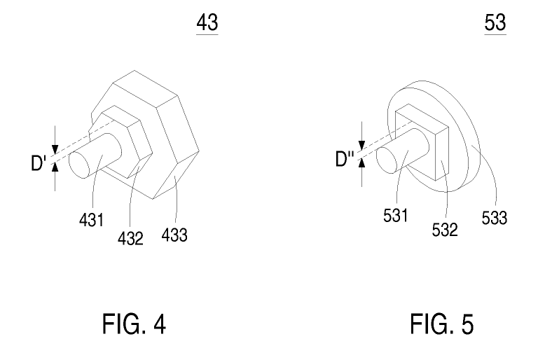

It is noted that numerous modifications and alterations may be made while retaining the teachings of the invention. FIG. 4 is a schematic perspective view illustrating another exemplary isolation member used in the assembled structure of the present invention. Similarly, the isolation member 43 has a stepped shape. The isolation member 43 comprises a first segment 431, a second segment 432 and a third segment 433. The outer diameter of the first segment 431 is smaller than the outer diameter of the second segment 432. The outer diameter of the second segment 432 is smaller than the outer diameter of the third segment 433. The first segment 431 is a cylindrical post, and the second segment 432 and the third segment 433 are polygonal posts (e.g. regular hexagonal posts). In addition, the first segment 431, the second segment 432 and the third segment 433 are coaxial with each other. Due to the gap D′ between the outer diameter of the second segment 432 and the outer diameter of the first segment 431, the insulating distance between the electronic component and the heat-dissipating device is increased.

FIG. 5 is a schematic perspective view illustrating another exemplary isolation member used in the assembled structure of the present invention. The isolation member 53 comprises a first segment 531, a second segment 532 and a third segment 533. The first segment 531 and the third segment 533 are cylindrical posts, and the second segment 532 is a rectangular post. The geometric centers of the first segment 531, the second segment 532 and the third segment 533 are arranged in the same line. That is, the first segment 531, the second segment 532 and the third segment 533 are coaxial with each other. Since the outer diameters of the first segment 531, the second segment 532 and the third segment 533 are gradually increased, the isolation member 53 has a stepped shape. Due to the gap D″ between the outer diameter of the second segment 532 and the outer diameter of the first segment 531, the insulating distance between the electronic component and the heat-dissipating device is increased.

In the above embodiments, the shapes of the first segment, the second segment and the third segment of the stepped isolation member may be modified or altered according to the practical requirements. That is, the profile of the isolation member is not restricted as long as the isolation member has a stepped shape, wherein the first segment is penetrated through the first perforation of the electronic component, the second segment is engaged with the second perforation of the heat-dissipating device and the third segment is contacted with the heat-dissipating device. Moreover, in the above embodiments, the first segment, the second segment and the third segment are coaxial with each other. In some embodiments, the first segment, the second segment and the third segment are not coaxial with each other as long as the minimum distance between the outer diameter of the first segment and the outer diameter of the second segment is sufficient to maintain electric safety.

In some embodiments, the washer and/or the insulating piece may be omitted. For example, if the first fastening element and the second fastening element are impossibly contacted with the electronic component, the washer may be eliminated. In addition, if the surface of the heat-dissipating device facing the electronic component is coated with an insulating material, the insulating piece may be eliminated.

In the above embodiment, the electronic component is fixed on the heat-dissipating device by means of the first fastening element and the second fastening element. In some embodiments, if the first segment of the isolation member is securely fixed in the third perforation of the insulating piece and the first perforation of the electronic component, the first fastening element and the second fastening element may be omitted. Meanwhile, the washer for isolating the second fastening element from the electronic component and the channel of the isolation member may be omitted. In some embodiments, the isolation member may be engaged between the electronic component and the heat-dissipating device.

From the above description, the stepped isolation member of the present invention comprises a first segment, a second segment and a third segment whose outer diameters are gradually increased. The first segment is partially accommodated within the first perforation of the electronic component, and the second segment is engaged with the second perforation of the heat-dissipating device. Due to the gap between the outer diameter of the second segment and the outer diameter of the first segment, the insulating distance between the electronic component and the heat-dissipating device is increased and the insulating efficacy is enhanced. In addition, by using the stepped isolation member of the present invention, the electric safety is enhanced without impairing the structural strength of the heat-dissipating device. In a case that the voltage applied to the electronic component increases, by adjusting the gap between the outer diameter of the second segment and the outer diameter of the first segment and adjusting the second perforation of the heat-dissipating device to accommodate the second segment, the insulating distance between the electronic component and the heat-dissipating device may be increased to enhance the insulating efficacy. That is, the insulating distance between the electronic component and the heat-dissipating device may be adjusted according to the practical requirements. As a consequence, the flexibility of adjusting the insulating distance is enhanced.

As previously described, since the electronic component is indirectly attached on the heat-dissipating device according to the prior art, the overall height of the assembled structure will be increased. Whereas, according to the assembled structure of the present invention, the electronic component is securely fixed on the heat-dissipating device and the electric safety is enhanced without increasing the overall height.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An assembled structure, comprising:
an electronic component having a first perforation;
a heat-dissipating device having a second perforation corresponding to said first perforation of said electronic component; and
a stepped isolation member comprising a first segment, a second segment and a third segment, wherein the outer diameter of said first segment is smaller than the outer diameter of said second segment, and the outer diameter of said second segment is smaller than the outer diameter of said third segment, wherein said first segment is partially accommodated within said first perforation of said electronic component, said second segment is arranged between said first segment and said third segment and engaged with said second perforation of said heat-dissipating device, and said third segment is contacted with said heat-dissipating device.

2. The assembled structure according to claim 1, further comprising an insulating piece, which is arranged between said electronic component and said heat-dissipating device and has a third perforation, wherein said first segment is partially accommodated within said third perforation of said insulating piece and said first perforation of said electronic component.

3. The assembled structure according to claim 2, wherein the diameter of said first perforation of said electronic component is substantially equal to the diameter of said third perforation of said insulating piece, but smaller than the diameter of said second perforation of said heat-dissipating device.

4. The assembled structure according to claim 1, wherein said first segment, said second segment and said third segment of said stepped isolation member are coaxial with each other, and said stepped isolation member further comprises a channel running through a centerline of said first segment, said second segment and said third segment.

5. The assembled structure according to claim 4, further comprising a first fastening element and a second fastening element, wherein said first fastening element comprises a head part and a body part, said body part of said first fastening element is penetrated through said channel of said stepped isolation member and coupled with second fastening element at a location beside said first segment, and said head portion of said first fastening element is contacted with said third segment.

6. The assembled structure according to claim 5, wherein a washer is further arranged between said electronic component and said second fastening element.

7. The assembled structure according to claim 1, wherein said first segment, said second segment and said third segment of said stepped isolation member are integrally formed.

8. The assembled structure according to claim 1, wherein said electronic component is a transistor, and said heat-dissipating device is a heat sink.

9. A stepped isolation member for use in an assembled structure of an electronic component and a heat-dissipating device, said electronic component having a first perforation, said heat-dissipating device having a second perforation corresponding to said first perforation, said stepped isolation member comprising:
a first segment;
a third segment; and
a second segment arranged between said first segment and said third segment, wherein the outer diameter of said first segment is smaller than the outer diameter of said second segment, and the outer diameter of said second segment is smaller than the outer diameter of said third segment, wherein said first segment is partially accommodated within said first perforation of said electronic component, said second segment is engaged with said second perforation of said heat-dissipating device, and said third segment is contacted with said heat-dissipating device.

10. The stepped isolation member according to claim 9, wherein said first segment, said second segment and said third segment of said stepped isolation member are coaxial with each other, and said stepped isolation member further comprises a channel running through a centerline of said first segment, said second segment and said third segment.
